(19) United States
(12) Patent Application Publication
(10) Pub. No.: US 2019/0378773 A1
(43) Pub. Date: Dec. 12, 2019

(54) GLASS ARTICLE HAVING A METALLIC NANOFILM AND METHOD OF INCREASING ADHESION BETWEEN METAL AND GLASS

(71) Applicant: CORNING INCORPORATED, Corning, NY (US)

(72) Inventors: Philip Simon Brown, Big Flats, NY (US); Shrisudersan Jayaraman, Horseheads, NY (US); Prantik Mazumder, Ithaca, NY (US); Rajesh Vaddi, Corning, NY (US)

(21) Appl. No.: 16/432,472

(22) Filed: Jun. 5, 2019

Related U.S. Application Data
(60) Provisional application No. 62/683,348, filed on Jun. 11, 2018.

(51) Int. Cl. H01L 23/15; C23C 18/18; C23C 18/32; C23C 18/38; C23C 18/16; C23C 28/02; C25D 5/54; C25D 7/12; C03C 17/36; C03C 17/38; H01L 23/498; H01L 21/48

(52) U.S. Cl. CPC H01L 23/15; C03C 2218/115; C23C 18/32; C23C 18/38; C23C 18/1653; C23C 28/02; C25D 5/54; C25D 7/12; C03C 17/3649; C03C 17/3642; C03C 17/38; H01L 23/49827; H01L 21/481; H01L 21/486; C03C 2217/256; C03C 2217/263; C03C 2218/116; C23C 18/18

(57) ABSTRACT

An article including a glass or glass ceramic substrate, a noble metal layer, an adhesion promoting layer positioned between and bonded to the substrate and the noble metal layer, and a conductive metal layer positioned on and bonded to the noble metal layer. The adhesion promoting layer includes a siloxy group bonded with the substrate and a thiol group bonded to the noble metal layer. A method for manufacturing an article including applying an adhesion promoting layer comprising mercaptosilane to at least a portion of a glass or glass ceramic substrate, wherein siloxane bonds are formed between the mercaptosilane and the substrate, applying a noble metal layer to the adhesion promoting layer, the noble metal layer bonds with a thiol present in the mercaptosilane, thermally treating the noble metal layer, and applying a conductive metal layer to the noble metal layer.

This application claims the benefit of priority to U.S. Provisional Application Ser. No. 62/683,348 filed on Jun. 11, 2018, the content of which is relied upon and incorporated herein by reference in its entirety.

### BACKGROUND

### Field

The present specification generally relates to glass or glass ceramic articles having a metallic nanofilm formed on a surface thereof and methods for increasing the adhesion between a conductive metal and glass or glass ceramic.

### Technical Background

Glass and glass ceramic substrates are used in components of electronic devices because the glass and glass ceramic substrates, generally, do not react with other components of the components, because they are they have a low dielectric constant, and because they are thermally stable. In particular, 3D interposers with through package via (TPV) interconnects that connect a logic device on one side of a substrate and memory on the other side of a substrate are becoming a hot trend for high bandwidth devices. To use glass or glass ceramic as a substrate for components of electronic devices, such as, for example, 3D interposers, a conductive metal layer is applied to one or more surfaces of the glass or glass ceramic substrate. However, conductive metals do not bond well with glass or glass ceramics.

Accordingly, a need exists for a method to increase the adhesion between glass or glass ceramics and a conductive metal to form glass or glass ceramic articles having a metallic nanofilm formed on a surface thereof.

### SUMMARY

According to one embodiment, an article comprises: a glass or glass ceramic substrate; a noble metal layer; an adhesion promoting layer positioned between and bonded to the glass or glass ceramic substrate and the noble metal layer; and a conductive metal layer positioned directly on and bonded to the noble metal layer. The adhesion promoting layer comprises a siloxy group bonded with the glass or glass ceramic substrate and a thiol group bonded to the noble metal layer.

In another embodiment, a method for manufacturing an article comprises: applying an adhesion promoting layer comprising mercaptosilane to at least a portion of a glass or glass ceramic substrate, wherein siloxane bonds are formed between the mercaptosilane and the glass or glass ceramic substrate; applying a noble metal layer to the adhesion promoting layer, wherein the noble metal layer bonds with a thiol present in the mercaptosilane; thermally treating the noble metal layer by heating and cooling the noble metal layer; and applying a conductive metal layer to the noble metal layer.

Additional features and advantages will be set forth in the detailed description which follows, and in part will be readily apparent to those skilled in the art from that description or recognized by practicing the embodiments described herein, including the detailed description which follows, the claims, as well as the appended drawings.

It is to be understood that both the foregoing general description and the following detailed description describe embodiments and are intended to provide an overview or framework for understanding the nature and character of the claimed subject matter. The accompanying drawings are included to provide a further understanding of the embodiments, and are incorporated into and constitute a part of this specification. The drawings illustrate the embodiments described herein, and together with the description serve to explain the principles and operations of the claimed subject matter.

### BRIEF DESCRIPTION OF THE DRAWINGS

FIG. 1 is a graph showing enthalpy of formation for various metal oxides;

FIG. 2 is a schematic of a cross section of an article according to embodiments disclosed and described herein;

FIG. 3A is a schematic of a cross section of an article comprising trenches according to embodiments disclosed and described herein;

FIG. 3B is a schematic of a cross section of an article comprising vias according to embodiments disclosed and described herein;

FIG. 4 is a schematic of the bonding between a substrate, an adhesion promoting layer, and a noble metal layer of an article according to embodiments disclosed and described herein;

FIG. 5 schematically depicts a method for forming an article according to embodiments disclosed and described herein;

FIG. 6 is a schematic of a cross section of an article having an additional metal layer according to embodiments disclosed and described herein;

FIG. 7 is a photograph of an article according to embodiments disclosed and described herein;

FIG. 8 is a photograph of substrate with a spin coated silver layer and an electroplated copper layer; and

FIG. 9 is a photograph of a substrate with a siloxy layer, a spin coated silver layer, and a copper layer that was electroplated to the silver layer using an acidic electroplating bath.

### DETAILED DESCRIPTION

Reference will now be made in detail to embodiments of methods for increasing the adhesion between glass or glass ceramics and a conductive metal to form glass or glass ceramic articles having a metallic nanofilm formed on a surface thereof. Whenever possible, the same reference numerals will be used throughout the drawings to refer to the same or like parts. In one embodiment, an article comprises a glass or glass ceramic substrate; a noble metal layer; an adhesion promoting layer positioned between and bonded to the glass or glass ceramic substrate and the noble metal layer; and a conductive metal layer positioned directly on and bonded to the noble metal layer. The adhesion promoting layer comprises a siloxy group bonded with the glass or glass ceramic substrate and a thiol group bonded to the noble metal layer. In another embodiment, a method for manufacturing an article comprises: applying an adhesion promoting layer comprising mercaptosilane to at least a portion of a glass or glass ceramic substrate, wherein siloxane bonds are formed between the mercaptosilane and the glass or glass ceramic substrate; applying a noble metal layer to the adhesion promoting layer, wherein the noble metal layer bonds with a thiol present in the mercaptosilane; thermally treating the noble metal layer by heating and cooling the noble metal layer; and applying a conductive metal layer to the noble metal layer.

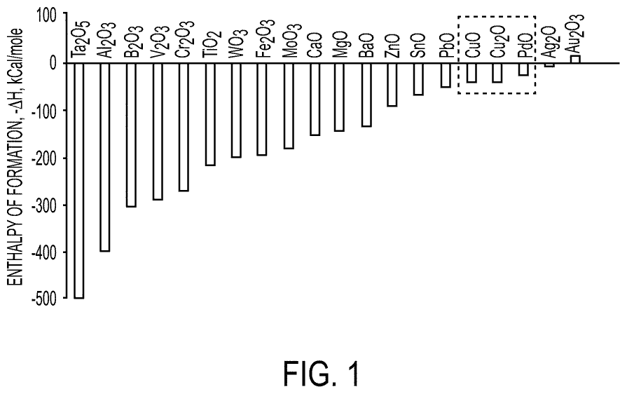

Various conducting metals do not intrinsically bond well to insulators such as glass and glass ceramics due to the fundamental difference in bonding nature between the materials. Glass and glass ceramics are covalently bonded materials and lack free electrons, which render them effective electrical insulators. On the other hand, the bonding in conductive metals is metallic in nature, which can be represented by stationary cationic nuclei and delocalized sea of electrons—the latter acting as “glue”. At the interface between the conducting metal and the glass or glass ceramic substrate there is no common bonding mechanism. However, as disclosed and described herein, if the conducting metal could easily form an oxide at the interface with the glass or glass ceramic substrate with high bond energy, that will enable strong adhesion between the two disparate materials (i.e., between the glass or glass ceramic and the conducting metal). The generally accepted criterion for good adhesion between a metal film and an oxide substrate is that the metal should be oxygen negative (i.e., metals that form oxides through highly exothermic reactions) to react chemically with the oxide surface, forming an interfacial reaction zone. FIG. 1 graphically shows the enthalpy of various oxides, in which a high negative enthalpy is an indicator of oxygen negativity. As can be seen in FIG. 1, oxides comprising tantalum, titanium, tungsten, and chromium, for example, have good oxygen negativity and are often used as metals to be bonded directly to glass or glass ceramic substrates. As can also be seen in FIG. 1, oxides of copper, silver, and gold have less negative enthalpy (i.e., closer to an enthalpy of 0), which indicates that these oxides are not good layers to bond to directly to glass or glass ceramic substrates. Embodiments of articles disclosed and described herein overcome this deficiency and provide increased adhesion between a glass or glass ceramic substrate and a conductive metal layer.

As described in more detail below, in various embodiments disclosed and described herein, this increased adhesion between the glass or glass ceramic substrate and the conducting metal is achieved by applying an adhesion promoting layer to a surface of the glass or glass ceramic substrate, applying a noble metal layer to a surface of the adhesion promoting layer, and applying the conductive metal to a surface of the noble metal layer.

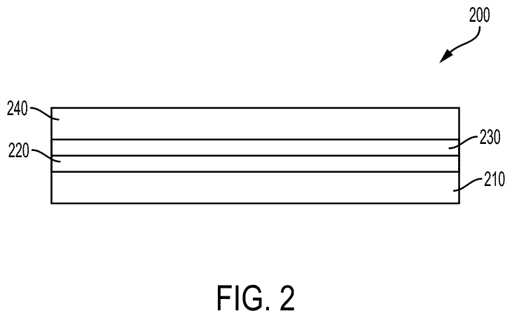

With reference now to FIG. 2, which is a cross section of an article 200 disclosed and described herein, an article 200 of such embodiments comprises a glass or glass ceramic substrate 210, an adhesion promoting layer 220, a noble metal layer 230, and a conductive metal layer 240. The articles disclosed and described herein have increased adhesion between the glass or glass ceramic substrate 210 and the conductive metal layer 240 when compared to articles where a conductive metal is applied directly to a glass or glass ceramic substrate. It should be understood that FIG. 2 is for illustrative purposes only and that the various layers of the article 200 depicted in FIG. 2 is are not necessarily drawn to scale. Each of the layers of the article 200 will be described in more detail below.

The composition of the glass or glass ceramic substrate 210 according to embodiments disclosed and described herein is not particularly limited and will, generally, be selected based upon the end use of the article and the required properties of the substrate. In embodiments, the composition of the glass or glass ceramic substrate 210 may be selected from the group consisting of aluminosilicate glass, alkali aluminosilicate glass, alkaline aluminosilicate glass, borosilicate glass, aluminoborosilicate glass, alkali aluminoborosilicate glass, alkaline aluminoborosilicate glass, soda-lime glass, fused quartz, fused silica, boron-phosphorous-silica glass ceramic, lithium-alumina-silica glass ceramic, magnesium-alumina-silica glass ceramic, zinc-alumina-silica glass ceramic. Similarly, the thickness and other dimensions of the glass or glass ceramic substrate will be determined by the end use of the component and are not limited herein. The glass or glass ceramic substrate may be formed by any suitable method known in the art.

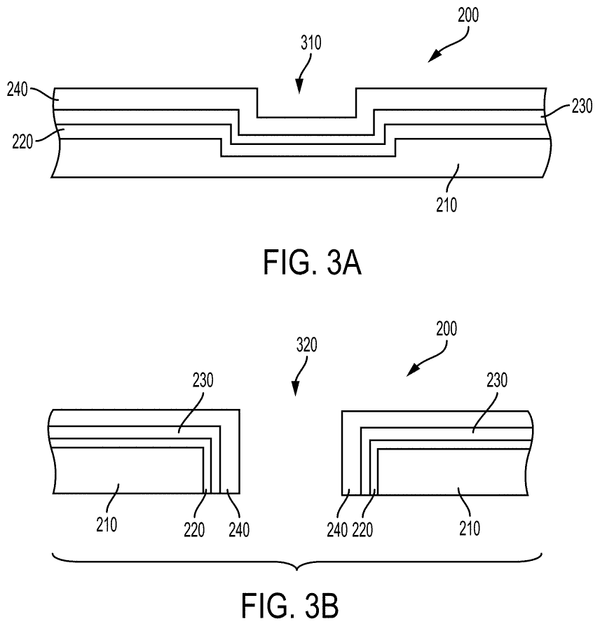

In some embodiments, the glass or glass ceramic substrate may have different geometries corresponding to the end use of the electrical component. With reference to FIG. 3A, which shows a portion of the article 200 comprising a groove, in some embodiments, the glass or glass ceramic substrate 210 comprises a trench 310. With reference to FIG. 3B, which shows a portion of the article 200 comprising a through via, in some embodiments, the glass or glass ceramic substrate 210 comprises a through via 320. With reference now to both FIG. 3A and FIG. 3B, it should be understood that each of these figures depict only a portion of the article 200 and the article 200 may include multiple trenches 310 or through vias 320, and in some embodiments, the article 200 may comprise both trenches 310 and through vias 320. It should be understood that FIGS. 3A and 3B are for illustrative purposes only and that the various layers (210, 220, 230, and 240), trenches (310), and through vias (320) of the article 200 depicted in FIGS. 3A and 3B are not necessarily drawn to scale.

In embodiments where the glass or glass ceramic substrate 210 comprises one or more trenches 310 and/or through vias 320, the adhesion promoting layer 220, the noble metal layer 230, and the conductive metal layer 240, which are deposited on the glass or glass ceramic substrate 210, will conform to the shape of the one or more trenches 310 and/or through vias 320 such that the article 200 comprises one or more trenches 310 and/or through vias 320 that correspond to the one or more trenches 310 and/or through vias 320 present in the glass or glass ceramic substrate 210. In this way, the glass or glass ceramic substrate 210 may be formed by conventional glass or glass ceramic forming methods to include trenches 310 and/or through vias 320 that are desired to be present in the article 200.

Although not depicted, in some embodiments, the adhesion promoting layer 220, the noble metal layer 230, and the conductive metal layer 240 may be applied only to parts of the glass or glass ceramic substrate 210, trenches 310, and/or through vias 320. Embodiments may be employed where it is desired that the one or more trenches 310 and/or through vias 320 that do not include the adhesion promoting layer 220, the noble metal layer 230, and the conductive metal layer 240 be electrically insulating.

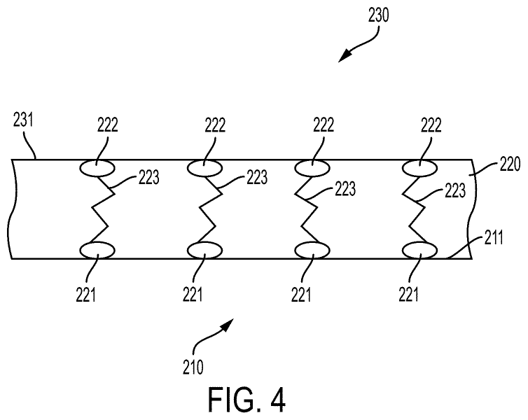

With reference again to FIG. 2, embodiments of the article 200 comprise an adhesion promoting layer 220 that is positioned between the glass or glass ceramic substrate 210 and the noble metal layer 230. FIG. 4 depicts a portion of the article 200 where the adhesion promoting layer 220 contacts the glass or glass ceramic substrate 210 and the noble metal layer 230, according to some embodiments. The glass or glass ceramic substrate 210 comprises a surface 211 that is substantially parallel to and opposite of a first surface 231 of the noble metal layer 230. The adhesion promoting layer 220 comprises a siloxy group 221 that is bonded to the surface 211 of the glass or glass ceramic substrate 210. The adhesion promoting layer further comprises a thiol group 222 that is bonded to the first surface 231 of the noble metal layer 230. Positioned between the siloxy group 221 and the thiol group 222 is a hydrocarbon chain 223 that connects the siloxy group 221 and the thiol group 222. In some embodiments, the hydrocarbon chain 223 that connects the siloxy group 221 and the thiol group 222 can comprise ether and organosilicon. The length of the hydrocarbon chain 223 is not particularly limited in embodiments. However, in some embodiments, the hydrocarbon chain 223 comprises less than or equal to 6 carbons, such as less than or equal to 5 carbons, less than or equal to 4 carbons, or less than or equal to 3 carbons. As used herein, a combination of the siloxy group 221, the thiol group 222, and the hydrocarbon chain 223 is referred to as the adhesion promoting structure.

The embodiment depicted in FIG. 4 shows a monolayer structure of the adhesion promoting layer 220. In the monolayer structure, the surface 211 of the glass or glass ceramic substrate 210 and the first surface 231 of the noble metal layer 230 are separated from one another by a distance that is approximately equal to the length of a single adhesion promoting structure. While in some embodiments the adhesion promoting layer 220 is a monolayer, in some embodiments, the surface 211 of the glass or glass ceramic substrate 210 and the first surface 231 of the noble metal layer 230 are separated from one another by a distance that is greater than the length of a single adhesion promoting structure. In embodiments, the thickness of the adhesion promoting layer 220 is less than or equal to 100 nm, such as less than or equal to 80 nm, less than or equal to 60 nm, less than or equal to 40 nm, less than or equal to 20 nm, or less than or equal to 10 nm. In some embodiments, the adhesion promoting layer has a thickness from greater than or equal to 1 nm to less than or equal to 100 nm, from greater than or equal to 10 nm to less than or equal to 80 nm, from greater than or equal to 20 nm to less than or equal to 60 nm, or from greater than or equal to 30 nm to less than or equal to 50 nm. The thickness of the adhesion promoting layer was measured using a Profilometer KLA Tencor D-600.

With reference again to FIG. 2, the article 200 comprises a noble metal layer 230 bonded to the adhesion promoting layer 220. As used herein, “noble metal” refers to the metals of Group 11 of the International Union of Pure and Applied Chemistry (IUPAC) periodic table and palladium. In some embodiments, the noble metal is selected from the group consisting of copper, silver, and gold. In some embodiments, the noble metal layer comprises silver. In some embodiments, the noble metal layer consists essentially of silver. With reference to FIG. 4, a first surface 231 of the noble metal layer 230 is bonded to the thiol group 222 present in the adhesion promoting layer 220. Thus, via the adhesion promoting layer 220, the noble metal layer 230 is adhered to the glass or glass ceramic substrate 210. As used herein, “consists essentially of” includes the listed components and unlisted components that do not materially affect the basic properties of the layer and/or article.

In some embodiments, the noble metal layer 230 has a thickness of less than or equal to 1 micron, such as less than or equal to 900 nm, less than or equal to 800 nm, less than or equal to 700 nm, less than or equal to 600 nm, less than or equal to 500 nm, less than or equal to 400 nm, less than or equal to 300 nm, or less than or equal to 200 nm. In some embodiments, the noble metal layer 230 has a thickness from greater than or equal to 100 nm to less than or equal to 500 nm, such as from greater than or equal to 150 nm to less than or equal to 500 nm, from greater than or equal to 200 nm to less than or equal to 500 nm, from greater than or equal to 250 nm to less than or equal to 500 nm, from greater than or equal to 300 nm to less than or equal to 500 nm, from greater than or equal to 350 nm to less than or equal to 500 nm, from greater than or equal to 400 nm to less than or equal to 500 nm, or from greater than or equal to 450 nm to less than or equal to 500 nm. In some embodiments, the noble metal layer 230 may has thickness from greater than or equal to 100 nm to less than or equal to 450 nm, from greater than or equal to 100 nm to less than or equal to 400 nm, from greater than or equal to 100 nm to less than or equal to 350 nm, from greater than or equal to 100 nm to less than or equal to 300 nm, from greater than or equal to 100 nm to less than or equal to 250 nm, from greater than or equal to 100 nm to less than or equal to 200 nm, or from greater than or equal to 100 nm to less than or equal to 150 nm. In some embodiments, the noble metal layer 230 has a thickness from greater than or equal to 150 nm to less than or equal to 450 nm, from greater than or equal to 200 nm to less than or equal to 400 nm, or from greater than or equal to 250 nm to less than or equal to 350 nm. The thickness of the noble metal layer was measured using a Profilometer KLA Tencor D-600.

As disclosed in the preceding paragraph, in embodiments, the noble metal layer 230 is a relatively thin layer. To achieve a thin noble metal layer 230, it is necessary to use small noble metal particles, such as nano-sized particles. The noble metal particles may be any shape or geometry provided that they are capable of achieving a noble metal layer with the thicknesses described in the preceding paragraph. In some embodiments, the noble metal particles are substantially spherical and have an average particle size of less than or equal to 100 nm, such as less than or equal to 90 nm, less than or equal to 80 nm, less than or equal to 70 nm, less than or equal to 60 nm, less than or equal to 50 nm, less than or equal to 40 nm, less than or equal to 30 nm, less than or equal to 20 nm, or less than or equal to 10 nm. In some embodiments, the noble metal particles have an average particle size from greater than or equal to 1 nm to less than or equal to 50 nm, such as from greater than or equal to 5 nm to less than or equal to 50 nm, from greater than or equal to 10 nm to less than or equal to 50 nm, from greater than or equal to 15 nm to less than or equal to 50 nm, from greater than or equal to 20 nm to less than or equal to 50 nm, from greater than or equal to 25 nm to less than or equal to 50 nm, from greater than or equal to 30 nm to less than or equal to 50 nm, from greater than or equal to 35 nm to less than or equal to 50 nm, or from greater than or equal to 40 nm to less than or equal to 50 nm. In some embodiments, the noble metal particles have an average particle size from greater than or equal to 1 nm to less than or equal to 45 nm, from greater than or equal to 1 nm to less than or equal to 40 nm, from greater than or equal to 1 nm to less than or equal to 30 nm, from greater than or equal to 1 nm to less than or equal to 35 nm, from greater than or equal to 1 nm to less than or equal to 30 nm, from greater than or equal to 1 nm to less than or equal to 25 nm, from greater than or equal to 1 nm to less than or equal to 20 nm, from greater than or equal to 1 nm to less than or equal to 15 nm, or from greater than or equal to 1 nm to less than or equal to 10 nm. In some embodiments, the noble metal particles have an average particle size from greater than or equal to 10 nm to less than or equal to 45 nm, from greater than or equal to 15 nm to less than or equal to 40 nm, from greater than or equal to 20 nm to less than or equal to 35 nm, or from greater than or equal to 25 nm to less than or equal to 30 nm. The average particle size of the noble metal particles is measured by transmission electron microscopy and dynamic light scattering. Where the noble metal particles are spherical or essentially spherical, the average particle size is an average of the diameters of the particles. Where the noble metal particles have an inconsistent shape, the average particle size is taken as an average of the largest length between opposing sides of the particles. For instance, where particles are ovoid (i.e., egg-shaped) the average particle size is taken as an average of the largest diameter of the ovoid.

In embodiments, the nano-sized particles may be nanowires. The nanowires, according to embodiments, have diameters less than or equal to 200 nm, such as less than or equal to 150 nm, less than or equal to 100 nm, or less than or equal to 50 nm. In each of the preceding embodiments, the nanowire may have a diameter of greater than or equal to 10 nm, such as greater than or equal to 20 nm, greater than or equal to 30 nm, or greater than or equal to 40 nm. The lengths of the nanowires used according to embodiments are larger than the diameter of the nanowires. In embodiments, the length of the nanowires may be greater than or equal to 0.5 μm, such as greater than or equal to 0.7 μm, greater than or equal to 0.9 μm, greater than or equal to 1.0 μm, greater than or equal to 1.5 μm, greater than or equal to 2.0 μm, greater than or equal to 2.5 μm, or greater than or equal to 3.0 μm. In any of the preceding embodiments, the length of the nanowires may be less than or equal to 5.0 μm, such as less than or equal to 4.5 μm, less than or equal to 4.0 μm, less than or equal to 3.5 μm, less than or equal to 3.0 μm, less than or equal to 2.5 μm, or less than or equal to 2.0 μm.

Without being bound by any particular theory, it is believed that by using noble metal nanoparticles, which can, for example, be applied directly to a glass substrate as part of a sol, to form the noble metal layer, a continuous noble metal layer may be formed directly on the glass substrate. This continuous noble metal layer may be used as an electrode that allows a conductive metal layer, such as, for example, copper, to be electroplated directly to the noble metal layer without needing an intermediate electroless plated layer between the noble metal layer and the conductive metal layer. In contrast, conventional methods apply a noble metal layer that is not composed of noble metal nanoparticles to a glass substrate. This noble metal layer is not suitable to act as an electrode for electroplating a conductive metal layer and an intermediate electroless plating layer (usually comprising the same material as the conductive metal layer) must be applied between the noble metal layer and the conductive metal layer. Not only does the addition of the intermediate electroless layer require additional method steps and materials, but the electroless layer also has a different structure than the conductive metal layer. For example, a layer of copper that has been applied by electroless plating will have a different grain structure than a copper layer that has been applied by electroplating. This difference in grain structure is ascertaining by inspection of a cross section of the article under a scanning electron microscope at magnification from, for example, ×5 k to ×100 k. As should now be recognized, articles and methods according to embodiments disclosed and described herein eliminate the need for this intermediate electroless layer.

As will be described in more detail herein, the noble metal layer 230 may be used as an electrode to electroplate the conductive metal layer 240 onto the noble metal layer 230. To achieve this electroplating, the noble metal layer 230 has, in some embodiments, a sheet resistance of less than or equal to 100 ohm/square, such as less than or equal to 80 ohm/square, less than or equal to 60 ohm/square, less than or equal to 40 ohm/square, less than or equal to 20 ohm/square, less than or equal to 10 ohm/square, less than or equal to 5 ohm/square, or less than or equal to 1 ohm/square. In some embodiments, the noble metal layer 230 has a sheet resistance from greater than or equal to 0.5 ohm/square to less than or equal to 100 ohm/square, from greater than or equal to 5 ohm/square to less than or equal to 100 ohm/square, from greater than or equal to 10 ohm/square to less than or equal to 100 ohm/square, from greater than or equal to 20 ohm/square to less than or equal to 100 ohm/square, from greater than or equal to 40 ohm/square to less than or equal to 100 ohm/square, from greater than or equal to 60 ohm/square to less than or equal to 100 ohm/square, or from greater than or equal to 80 ohm/square to less than or equal to 100 ohm/square. In some embodiments, the noble metal layer 230 has a sheet resistance from greater than or equal to 1 ohm/square to less than or equal to 100 ohm/square, such as from greater than or equal to 1 ohm/square to less than or equal to 80 ohm/square, from greater than or equal to 1 ohm/square to less than or equal to 60 ohm/square, from greater than or equal to 1 ohm/square to less than or equal to 40 ohm/square, from greater than or equal to 1 ohm/square to less than or equal to 20 ohm/square, or from greater than or equal to 1 ohm/square to less than or equal to 10 ohm/square. In some embodiments, the noble metal layer 230 has a sheet resistance from greater than or equal to 10 ohm/square to less than or equal to 100 ohm/square, such as from greater than or equal to 40 ohm/square to less than or equal to 100 ohm/square, or from greater than or equal to 60 ohm/square to less than or equal to 100 ohm/square. The sheet resistance is measured with a ResMap 178 four point probe manufactured by Creative Design Engineering, Inc. The sheet resistance is measured after the deposition of the noble metal layer, but before the conductive metal layer is applied to the noble metal layer.

With reference again to FIG. 2, the article 200 comprises a conductive metal layer 240 positioned on, and bonded to, the noble metal layer 230. Thus, the conductive metal layer 240 is bonded to the glass or glass ceramic substrate 210 via the adhesion promoting layer 220 and the noble metal layer 230. As used herein, a conductive metal includes all of Groups 1 to 12 of the IUPAC periodic table of elements—excluding hydrogen—aluminum, gallium, indium, thallium, tin, lead, bismuth, and polonium. In some embodiments, the conductive metal layer 240 comprises at least one selected from the group consisting of copper, nickel, cobalt, gold, silver, cadmium, chromium, lead, platinum, tin, and combinations and alloys thereof. In some embodiments, the conductive metal layer 240 comprises copper. In some embodiments, the conductive metal layer 240 consists essentially of copper. The composition and thickness of the conductive metal layer 240 is not particularly limited and will depend upon the end use of the article 200. It should be understood that in embodiments, no layer is intentionally formed between the noble metal layer and the conductive metal layer. And, as used herein, any oxidation that naturally occurs at the surface of the noble metal layer or the conductive metal layer are included in the definition of these layers and do not constitute distinct layers. Thus, a conductive metal layer formed on a naturally occurring oxide of the noble metal layer constitutes the conductive metal layer being directly deposited on the noble metal layer.

In embodiments, the conductive metal layer 240 is a relatively thick layer. In some embodiments, the conductive metal layer 240 has a thickness from greater than or equal to 10 microns to less than or equal to 500 microns, such as from greater than or equal to 20 microns to less than or equal to 200 microns, from greater than or equal to 30 microns to less than or equal to 100 microns, from greater than or equal to 40 microns to less than or equal to 70 microns, or from greater than or equal to 50 microns to less than or equal to 60 microns.

As discussed previously, the article 200 of embodiments disclosed and described herein has improved adhesion between the glass or glass ceramic substrate 210 and the conductive metal layer 240 when compared to articles where a conductive metal is applied to a glass or glass ceramic substrate. The adhesion of the conductive metal layer 240 to the glass or glass ceramic substrate 210 may be measured using a tape test according to ASTM standard D3359 using a tape that has an adhesion of 3 N/cm.

The preceding disclosure provides descriptions of embodiments of articles 200 comprising a glass or glass ceramic substrate 210, an adhesion promoting layer 220, a noble metal layer 230, and a conductive metal layer 240. Hereinafter, methods for forming the articles 200 according to embodiments will be described.

As noted above, the glass or glass ceramic substrate 210 may be formed by any suitable method for forming glass or glass ceramics. In embodiments, the glass or glass ceramic substrate 210 may be formed to have trenches 310 or through vias 320. The trenches 310 in the glass or glass ceramic substrate 210 may be formed by any type of glass or glass ceramic molding or forming method. The through vias 320 may be formed by any suitable method including laser ablation, etching, and mechanic drilling (such as, for example, with a computer numerical control (CNC) machine). As previously disclosed, the adhesion promoting layer 220, noble metal layer 230, and conductive metal layer 240 may or may not be formed in the trenches 310 or through vias 320. In embodiments where the adhesion promoting layer 220, noble metal layer 230, and conductive metal layer 240 are not formed in the trenches 310 and through vias 320, the trenches 310 and through vias 320 in which these layers are not desired may be masked by a suitable masking agent during the methods subsequently described, and the masking agent may be removed once the process is complete. Alternatively, the methods for forming an article subsequently described may be applied with precision only to the trenches 310 and through vias 320 where it is desirable to form the adhesion promoting layer 220, noble metal layer 230, and conductive metal layer 240.

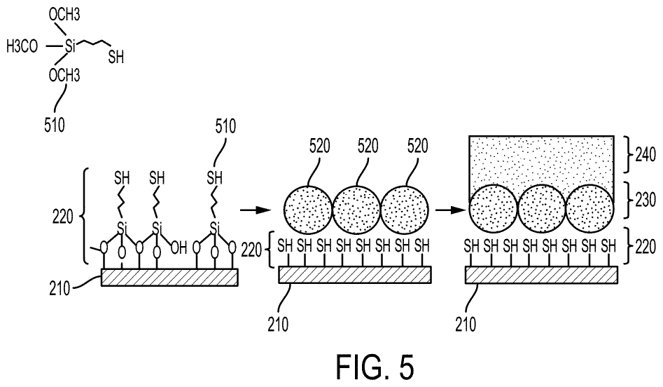

In embodiments, the adhesion promoting layer 220 is formed on the glass or glass ceramic substrate 210 by applying a mercaptosilane or imidazole silane to at least a portion of the glass or glass ceramic substrate 210 on which a conductive metal layer 240 is to be formed. In some embodiments, a mercaptosilane or imidazole silane is applied to the glass or glass ceramic substrate. In some embodiments, this portion of the glass or glass ceramic substrate 210 may be an entire surface of the glass or glass ceramic substrate 210, and in some embodiments, the portion of the glass or glass ceramic substrate 210 may be less than an entire surface of the glass or glass ceramic substrate 210. The mercaptosilane or imidazole silane may be applied to a portion of the glass or glass ceramic substrate 210 by any suitable method and, in some embodiments, the mercaptosilane or imidazole silane is applied to the glass or glass ceramic substrate 210 by one of dip coating, spin coating, spray coating, and vapor deposition. In some embodiments, soxhlet extraction can be used to remove excess, unbound material. With reference to FIG. 5 (which shows embodiments using a mercaptosilane), once applied to the glass or glass ceramic substrate 210, the mercaptosilane 510 will self-assemble such that the silanized portion of the mercaptosilane 510 forms a siloxane bond between the glass or glass ceramic substrate 210 and the mercaptosilane 510. In turn, this self-assembly leaves the thiol group of the mercaptosilane 510 unreacted and available to form bonds with other layers of the article. Without being bound by any particular theory, it is believed that the S—H bond in the thiol group is a weak polar bond compared, for example, to an O—H bond in an alcohol and, thus, the hydrogen in the thiol may disassociate leaving the sulfur of the thiol free to bond to the noble metal. Although the exact chemistry that occurs to bond sulfur to noble metals, such as, for example, silver and gold, is not entirely understood, it is well known that such bonding does occur. In some embodiments, the adhesion promoting layer 220 can be formed by spin coating at a speed of 1000 rpm for 30 seconds. In some embodiments, the mercaptosilane is (3-mercaptopropyl)-trimethoxysilane, (3-mercaptopropyl)-methyl-dimethoxysilane, or (3-mercaptopropyl)-triethoxysilane. Other mercaptosilanes can also be used in some embodiments, such as, for example, those disclosed in U.S. Pat. No. 8,187,716, which is hereby incorporated by reference in its entirety. In some embodiments, the imidazole silane is selected from N-(3-trimethoxysilylpropyl)imidazole or N-(3-triethoxysilylpropyl)imidazole.

According to embodiments, once the adhesion promoting layer 220 is applied to the glass or glass ceramic substrate 210—such as by applying a mercaptosilane to the glass or glass ceramic substrate 210—the noble metal layer 230 is applied to the adhesion promoting layer 220. As shown in FIG. 5, the noble metal particles 520 that form the noble metal layer 230 bond with the thiol portion of the mercaptosilane 510 that is available from the previously described self-assembly of the mercaptosilane 510 on the glass or glass ceramic substrate 210. In embodiments, the noble metal layer 230 is applied to the adhesion promoting layer 220 by one of dip coating, spin coating, and spray coating.

As previously described, in some embodiments, the noble metal layer 230 has a low sheet resistance. One way that this low sheet resistance may be achieve is by controlling the coating process during application of the noble metal layer 230 to the adhesion promoting layer 220. Initially, noble metal nanoparticles—as previously described in detail—may be added to a solvent to form a colloidal suspension (i.e., a sol). The liquid material used for the colloidal suspension of the noble metal nanoparticles is, in embodiments, selected from non-polar liquids, such as, for example, hexane, heptane, and cyclohexane. In some embodiments the liquid used in the colloidal suspension is cyclohexane or ethylcyclohexane. This colloidal suspension of noble metal nanoparticles may be used to apply the noble metal layer to the adhesion promoting layer, such as by spray coating or spin coating.

Accordingly, in some embodiments, the noble metal layer 230 is applied to the adhesion promoting layer 220 by spin coating the noble metal layer 230 onto the adhesion promoting layer 220 at a speed from greater than or equal to 500 rpm to less than or equal to 4500 rpm, such as from greater than or equal to 700 rpm to less than or equal to 4300 rpm, from greater than or equal to 900 rpm to less than or equal to 4100 rpm, from greater than or equal to 1000 rpm to less than or equal to 3900 rpm, from greater than or equal to 1200 rpm to less than or equal to 3700 rpm, from greater than or equal to 1400 rpm to less than or equal to 3500 rpm, from greater than or equal to 1600 rpm to less than or equal to 3300 rpm, from greater than or equal to 1800 rpm to less than or equal to 3100 rpm, from greater than or equal to 2000 rpm to less than or equal to 2900 rpm, or from greater than or equal to 2200 rpm to less than or equal to 2700 rpm. In some embodiments, the noble metal layer 230 is spin coated onto the adhesion promoting layer 220 at a speed ranging from greater than or equal to 500 rpm to 1500 rpm, such as from greater than or equal to 700 rpm to less than or equal to 1300 rpm, from greater than or equal to 900 rpm to less than or equal to 1100 rpm, or about 1000 rpm. It should be understood that at lower speeds the noble metal layer 230 will be thicker and denser, and at higher speeds the noble metal layer 230 will be thinner and less dense.

Once the noble metal layer 230 is applied to the adhesion promoting layer 220, the noble metal layer 230 may be thermally treated. The thermal treatment process, like the deposition process, has an effect on the sheet resistivity of the noble metal layer 230. In some embodiments, the noble metal layer 230 is thermally treated by heating the noble metal layer to temperatures from greater than or equal to 150° C. to less than or equal to 700° C., such as from greater than or equal to 200° C. to less than or equal to 700° C., from greater than or equal to 250° C. to less than or equal to 700° C., from greater than or equal to 300° C. to less than or equal to 700° C., from greater than or equal to 350° C. to less than or equal to 700° C., from greater than or equal to 400° C. to less than or equal to 700° C., from greater than or equal to 450° C. to less than or equal to 700° C., from greater than or equal to 500° C. to less than or equal to 700° C., from greater than or equal to 550° C. to less than or equal to 700° C., from greater than or equal to 600° C. to less than or equal to 700° C., or from greater than or equal to 650° C. to less than or equal to 700° C. In some embodiments, the noble metal layer 230 is thermally treated by heating the noble metal layer to temperatures from greater than or equal to 150° C. to less than or equal to 650° C., from greater than or equal to 150° C. to less than or equal to 600° C., from greater than or equal to 150° C. to less than or equal to 550° C., from greater than or equal to 150° C. to less than or equal to 500° C., from greater than or equal to 150° C. to less than or equal to 450° C., from greater than or equal to 150° C. to less than or equal to 400° C., from greater than or equal to 150° C. to less than or equal to 350° C., from greater than or equal to 150° C. to less than or equal to 300° C., from greater than or equal to 150° C. to less than or equal to 250° C., or from greater than or equal to 150° C. to less than or equal to 200° C. In some embodiments, the noble metal layer 230 is thermally treated by heating the noble metal layer to temperatures from greater than or equal to 150° C. to less than or equal to 350° C., such as from greater than or equal to 175° C. to less than or equal to 350° C. from greater than or equal to 200° C. to less than or equal to 350° C., from greater than or equal to 225° C. to less than or equal to 350° C., from greater than or equal to 250° C. to less than or equal to 350° C., from greater than or equal to 275° C. to less than or equal to 350° C., from greater than or equal to 300° C. to less than or equal to 350° C., or from greater than or equal to 325° C. to less than or equal to 350° C. In some embodiments, the noble metal layer 230 is thermally treated by heating the noble metal layer to temperatures from greater than or equal to 150° C. to less than or equal to 325° C., from greater than or equal to 150° C. to less than or equal to 300° C., from greater than or equal to 150° C. to less than or equal to 275° C., from greater than or equal to 150° C. to less than or equal to 250° C., from greater than or equal to 150° C. to less than or equal to 225° C., from greater than or equal to 150° C. to less than or equal to 200° C., or from greater than or equal to 150° C. to less than or equal to 175° C. This thermal treatment may be conducted in an ambient atmosphere, such as air.

When any of the preceding thermal treatment temperatures are used, the noble metal layer 230 may be held at the thermal treatment temperature for a suitable duration to allow the thermal treatment to fully proceed. In embodiments, the noble metal layer 230 is held at the thermal treatment temperature for a duration from greater than or equal to 1 min to less than or equal to 10 min, such as from greater than or equal to 1 min to less than or equal to 9 min, from greater than or equal to 1 min to less than or equal to 8 min, from greater than or equal to 1 min to less than or equal to 7 min, from greater than or equal to 1 min to less than or equal to 6 min, from greater than or equal to 1 min to less than or equal to 5 min, from greater than or equal to 1 min to less than or equal to 4 min, from greater than or equal to 1 min to less than or equal to 3 min, or from greater than or equal to 1 min to less than or equal to 2 min. In some embodiments the noble metal layer 230 is held at the thermal treatment temperature for a duration from greater than or equal to 2 min to less than or equal to 10 min, such as from greater than or equal to 3 min to less than or equal to 10 min, from greater than or equal to 4 min to less than or equal to 10 min, from greater than or equal to 5 min to less than or equal to 10 min, from greater than or equal to 6 min to less than or equal to 10 min, from greater than or equal to 7 min to less than or equal to 10 min, from greater than or equal to 8 min to less than or equal to 10 min, or from greater than or equal to 9 min to less than or equal to 10 min. In some embodiments, the noble metal layer 230 is held at the thermal treatment temperature for a duration from greater than or equal to 1 min to less than or equal to 3 min, such as about 2 min. It should be understood that the duration of will increase as the thermal treatment temperature decreases. For instance, at a thermal treatment temperature of 350° C. the duration that the noble metal layer 230 is held at the thermal treatment temperature may be 2 min, but at a thermal treatment temperature of 150° C. the duration that the noble metal layer 230 is held at the thermal treatment temperature may be 10 min.

Regardless of the thermal treatment temperature to which the noble metal layer 230 is heated and the duration that the noble metal layer 230 is held at the thermal treatment temperature, after the duration of the thermal treatment temperature is complete, the noble metal layer 230 is cooled to room temperature. The noble metal layer 230 may be cooled by any suitable method, and controlled cooling is not required in some embodiments. The thermal treatments disclosed and described herein sinters the noble metal nanoparticles that comprise the noble metal layer, thereby increasing the conductivity of the noble metal layer and making it more suitable for use as an electrode in for electroplating the conductive metal layer.

Once the noble metal layer 230 is thermally treated, the conductive metal layer 240 may be applied to the noble metal layer 230. In embodiments, the conductive metal layer 240 is applied to the noble metal layer 230 by electroplating. It should be understood that the chemistry used for electroplating various conductive metals will depend upon the conductive metals that are to be electroplated onto the noble metal layer 230. Any suitable electroplating process may be used to deposit a conductive metal layer 240 to the noble metal layer 230. In some embodiments, the noble metal layer 230 may be used as an electrode in the electroplating process, such that the conductive metal layer 240 is applied directly to the noble metal layer 230.

It should be understood that the electroplating process is selected to be compatible with both the noble metal in the noble metal layer 230 and the conductive metal in the conductive metal layer 240. As an example, when silver is used as the noble metal in the noble metal layer 230 and copper is used as the conductive metal in the conductive metal layer 240, a non-acidic electroplating bath should be used for electroplating the copper onto the silver noble metal layer 230. If an acidic electroplating bath is used in conjunction with a silver noble metal layer 230, the acid will react with the silver and prevent good adhesion between the conductive metal layer 240 and the glass or glass ceramic substrate 210. To counteract this effect with silver, in some embodiments, an electroplating process will comprise an amount of non-acid plating—that plates the silver—followed by acid plating. It should be understood that acid may be detrimental to other metal layer as well; not just silver.

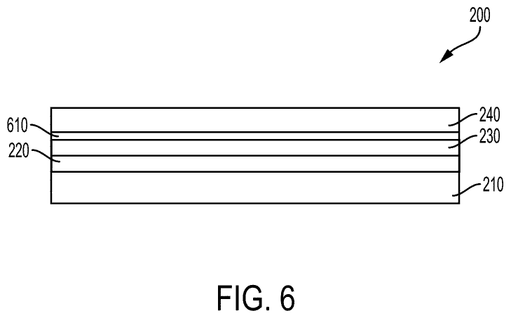

With reference to FIG. 6, in some embodiments, an additional metal layer 610 is applied to the noble metal layer 230 by electroless plating, and the conductive metal layer 240 is applied to the additional metal layer 610 by electroplating. In embodiments, the additional metal layer 610 may be applied by any suitable electroless plating process. Further, according to some embodiments, the additional metal layer 610 is used as an electrode for electroplating the conductive metal layer 240 to the additional metal layer 610. In some embodiments, the additional metal layer 610 comprises copper, nickel, or cobalt. In some embodiments, the additional metal layer 610 consists essentially of copper.

A first clause comprises an article (200) comprising: a glass or glass ceramic substrate (210); a noble metal layer (230); an adhesion promoting layer (220) positioned between and bonded to the glass or glass ceramic substrate (210) and the noble metal layer; and a conductive metal layer (240) positioned on and bonded to the noble metal layer (230), wherein the adhesion promoting layer (220) comprises a siloxy group bonded with the glass or glass ceramic substrate (210) and a thiol group bonded to the noble metal layer (230).

A second clause comprises the article (200) of the first clause, wherein the noble metal layer (230) is a noble metal selected from the group consisting of copper, silver, and gold.

A third clause comprises the article (200) of any one of the first and second clauses, wherein the noble metal layer (230) consists essentially of silver.

A fourth clause comprises the article (200) of any one of the first to third clauses, wherein the conductive metal layer (240) is a conductive metal selected from the group consisting of copper, nickel, cobalt, gold, silver, cadmium, chromium, lead, platinum, and combinations and alloys thereof.

A fifth clause comprises the article (200) of any one of the first to fourth clauses, wherein the conductive metal layer (240) consists essentially of copper.

A sixth clause comprises the article (200) of any one of the first to fifth clauses, wherein the adhesion promoting layer (220) is a monolayer.

A seventh clause comprises the article (200) of any one of the first to sixth clauses, wherein the adhesion promoting layer (220) has a thickness of less than 100 nm.

An eighth clause comprises the article (200) of any one of the first to seventh clauses, wherein the noble metal layer (230) has a thickness of less than one micron.

A ninth clause comprises the article (200) of any one of the first to eighth clauses, wherein the noble metal layer (230) has a thickness from greater than or equal to 100 nm to less than or equal to 500 nm.

A tenth clause comprises the article (200) of any one of the first to ninth clauses, wherein the noble metal layer (230) is made from noble metal particles having an average particle size of less than or equal to 100 nm.

An eleventh clause comprises the article (200) of any one of the first to tenth clauses, wherein the noble metal layer (230) is made from noble metal particles having an average particle size from greater than or equal to 5 nm to less than or equal to 50 nm.

A twelfth clause comprises the article (200) of any one of the first to eleventh clauses, wherein the noble metal layer (230) has a sheet resistance of less than 500 ohm/square.

A thirteenth clause comprises the article (200) of any one of the first to twelfth clauses, wherein the glass or glass ceramic substrate (210) comprises vias (320) and/or trenches (310) and the adhesion promoting layer (220), noble metal layer (230), and conductive metal layer (240) are present in the vias (320) and/or trenches (310).

A fourteenth clause comprises the article (200) of any one of the first to thirteenth clauses, wherein the adherence of the conductive metal layer (240) to the article (200) is such that it passes a tape test at 3.0 N/cm.

A fifteenth clause comprises a method for manufacturing an article (200) comprising: applying an adhesion promoting layer (220) comprising mercaptosilane (510) to at least a portion of a glass or glass ceramic substrate (210), wherein siloxane bonds are formed between the mercaptosilane (510) and the glass or glass ceramic substrate (210); applying a noble metal layer (230) to the adhesion promoting layer (220), wherein the noble metal layer (230) bonds with a thiol present in the mercaptosilane (510); thermally treating the noble metal layer (230) by heating and cooling the noble metal layer (230); and applying a conductive metal layer (240) to the noble metal layer (230).

A sixteenth clause comprises the method of the fifteenth clause, wherein the noble metal layer (230) comprises a noble metal selected from the group consisting of copper, silver, and gold.

A seventeenth clause comprises the method of any one of the fifteenth and sixteenth clauses, wherein the noble metal layer (230) comprises silver.

An eighteenth clause comprises the method of any one of the fifteenth to seventeenth clauses, wherein the conductive metal layer (240) is a conductive metal selected from the group consisting of copper, nickel, cobalt, gold, silver, cadmium, chromium, lead, platinum, and combinations and alloys thereof.

A nineteenth clause comprises the method of any one of the fifteenth to eighteenth clauses, wherein the conductive metal layer (240) is copper.

A twentieth clause comprises the method of any one of the fifteenth to nineteenth clauses, wherein the noble metal layer (230) has a thickness of less than one micron.

A twenty first clause comprises the method of any one of the fifteenth to twentieth clauses, wherein the noble metal layer (230) comprises noble metal particles (520) having an average particle size of less than or equal to 100 nm.

A twenty second clause comprises the method of any one of the fifteenth to twenty first clauses, wherein thermally treating the noble metal comprises heating the noble metal to a temperature from greater than or equal to 150° C. to less than or equal to 700° C. and cooling to room temperature.

A twenty third clause comprises the method of any one of the fifteenth to twenty second clauses, wherein thermally treating the noble metal comprises heating the noble metal to a temperature from greater than or equal to 150° C. to less than or equal to 350° C. and cooling to room temperature.

A twenty fourth clause comprises the method of any one of the fifteenth to twenty third clauses, wherein the conductive metal layer (240) is applied to the noble metal layer (230) by electroplating.

A twenty fifth clause comprises the method of the twenty fourth clause, wherein the noble metal layer (230) is used as an electrode for electroplating the conductive metal layer (240) to the noble metal layer (230).

A twenty sixth clause comprises the method of any one of the fifteenth to twenty fifth clauses, wherein an additional metal layer (610) is applied to the noble metal layer (230) by electroless plating, and the conductive metal layer (240) is applied to the additional metal layer (610) by electroplating.

A twenty seventh clause comprises the method of the twenty sixth clause, wherein the additional metal layer (610) comprises a member selected from the group consisting of copper, nickel, and cobalt.

A twenty eighth clause comprises the method of the twenty sixth clause, wherein the additional metal layer consists essentially of copper.

### EXAMPLES

Embodiments will be further clarified by the following examples.

### Example 1

Square 50 mm substrates made from Eagle XG glass manufactured by Corning Incorporated having thicknesses of 0.7 mm were immersed in 2% (v/v) (3-Mercaptopropyl)trimethoxysilane (mercapto-silane) in toluene solution for 30 mins. The substrates were rinsed in toluene and dried under nitrogen. The samples were then baked in an oven at 120° C. for 30 min. Silver nanoparticles (10-13 nm, manufactured by Cerion) were dispersed in ethylcylcohexane at a concentration of 20% (w/v). The suspension was sonicated for 30 min to help break up particle agglomerates. The suspension was then spin coated onto substrates at 1000 rpm. The resulting silver thin films were then thermally treated in a rapid thermal process (RTP) oven under various conditions provided in Table 1 below. The sheet resistance of the thermally treated films was measured at multiple locations on each sample using a four-point probe. It was found the sheet resistance after thermal treatment did not significantly vary with the addition of silane, as shown in Table 1.

TABLE 1

| | Thermal | | |
|---|---|---|---|
| | Treatment | Time | Sheet Resistance |
| Silane | Temp.(° C) | (min) | (Ohm/square) |
| No | 150 | 10 | 71k |
| No | 350 | 2 | 1.5 |
| Yes | 150 | 10 | 73k |
| Yes | 350 | 2 | 1.3 |

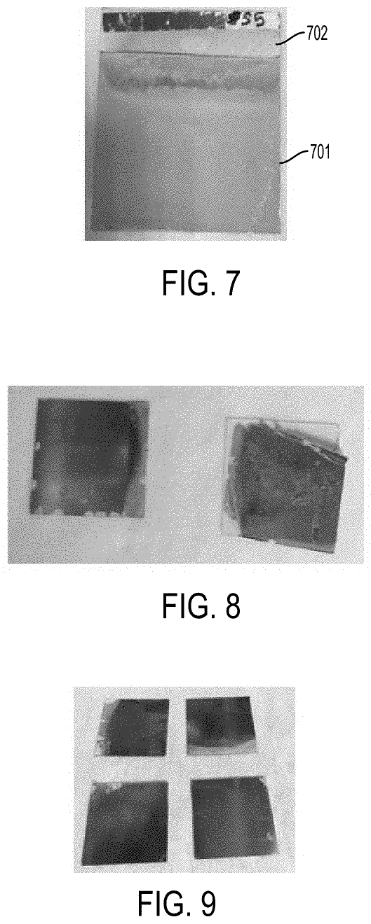

The samples were then immersed in a 1 M copper sulfate solution and plating was carried out at −0.3 V constant voltage for 6 h, with a copper sheet acting as an anode. The resulting electroplated copper was found to be about 18.4 μm thick. A resulting article is shown in FIG. 7 and comprises an electroplated copper layer 701 and a silver layer 702. The article survived drying and the tape test conducted according to ASTM standard D3359 using table with a strength of 3 N/cm.

### Comparative Example 1

Silver nanoparticles (10-13 nm, manufactured by Cerion) were dispersed in ethylcylcohexane at a concentration of 20% (w/v). The suspension was sonicated for 30 min to help break up particle agglomerates. The suspension was then spin coated onto substrates as used in Example 1 at 1000 rpm.

The samples were then immersed in a 1 M copper sulfate solution and plating was carried out at −0.3 V constant voltage for 6 h, with a copper sheet acting as an anode. As shown in FIG. 8, the article did not survive drying, which shows that the addition of a silane leads to much improved adhesion.

### Comparative Example 2

Substrates as described in Example 1 were immersed in 2% (v/v) (3-Mercaptopropyl)trimethoxysilane (mercapto-silane) in toluene solution for 30 mins. The substrates were rinsed in toluene and dried under nitrogen. The samples were then baked in an oven at 120° C. for 30 min. Silver nanoparticles (10-13 nm, manufactured by Cerion) were dispersed in ethylcylcohexane at a concentration of 20% (w/v). The suspension was sonicated for 30 min to help break up particle agglomerates. The suspension was then spin coated onto substrates at 1000 rpm. The resulting silver thin films were then thermally treated in an RTP oven under various conditions provided in Table 1 above. The sheet resistance of the thermally treated films was measured at multiple locations on each sample using a four-point probe. It was found the sheet resistance after thermal treatment did not significantly vary with the addition of silane, as shown in Table 1 above.

The samples were then mounted to a conductive plate and immersed in the plating bath comprising H₂SO₄. Electroplating was carried out using constant current of 500 mA for 2 h. The resulting electroplated copper was found to be about 8 μm thick. As shown in FIG. 9, the article survived drying, but did not pass the tape test according to ASTM standard D3359 using table with a strength of 3 N/cm. This shows that proper electroplating processes should be conducted.

It will be apparent to those skilled in the art that various modifications and variations can be made to the embodiments described herein without departing from the spirit and scope of the claimed subject matter. Thus it is intended that the specification cover the modifications and variations of the some embodiments described herein provided such modification and variations come within the scope of the appended claims and their equivalents.

What is claimed is:

1. An article comprising:
a glass or glass ceramic substrate;
a noble metal layer;
an adhesion promoting layer positioned between and bonded to the glass or glass ceramic substrate and the noble metal layer; and
an electroplated conductive metal layer positioned directly on and bonded to the noble metal layer,
wherein the adhesion promoting layer comprises a siloxy group bonded with the glass or glass ceramic substrate and a thiol group bonded to the noble metal layer.

2. The article of claim 1, wherein the noble metal layer comprises a noble metal selected from the group consisting of copper, silver, and gold.

3. The article of claim 1, wherein the noble metal layer consists essentially of silver.

4. The article of claim 1, wherein the electroplated conductive metal layer is a conductive metal selected from the group consisting of copper, nickel, cobalt, gold, silver, cadmium, chromium, lead, platinum, and combinations and alloys thereof.

5. The article of claim 1, wherein the electroplated conductive metal layer consists essentially of copper.

6. The article of claim 1, wherein the adhesion promoting layer is a monolayer.

7. The article of claim 1, wherein the adhesion promoting layer has a thickness of less than 100 nm.

8. The article of claim 1, wherein the noble metal layer has a thickness of less than one micron.

9. The article of claim 1, wherein the noble metal layer is made from noble metal particles having an average particle size of less than or equal to 100 nm.

10. The article of claim 1, wherein the noble metal layer has a sheet resistance of less than 500 ohm/square.

11. The article of claim 1, wherein the glass or glass ceramic substrate comprises vias and/or trenches and the adhesion promoting layer, the noble metal layer, and the electroplated conductive metal layer are present in the vias and/or trenches.

12. A method for manufacturing an article comprising:
applying an adhesion promoting layer comprising mercaptosilane to at least a portion of a glass or glass ceramic substrate, wherein siloxane bonds are formed between the mercaptosilane and the glass or glass ceramic substrate;
applying a noble metal layer to the adhesion promoting layer, wherein the noble metal layer bonds with a thiol present in the mercaptosilane;
thermally treating the noble metal layer by heating and cooling the noble metal layer; and
electroplating a conductive metal layer to the noble metal layer.

13. The method of claim 12, wherein the noble metal layer comprises a noble metal selected from the group consisting of copper, silver, and gold.

14. The method of claim 12, wherein the conductive metal layer is a conductive metal selected from the group consisting of copper, nickel, cobalt, gold, silver, cadmium, chromium, lead, platinum, and combinations and alloys thereof.

15. The method of claim 12, wherein thermally treating the noble metal layer comprises heating the noble metal to a temperature from greater than or equal to 150° C. to less than or equal to 700° C. and cooling to room temperature.

16. The method of claim 12, wherein thermally treating the noble metal layer comprises heating the noble metal to a temperature from greater than or equal to 150° C. to less than or equal to 350° C. and cooling to room temperature.

17. The method claim 12, wherein the conductive metal layer is applied to the noble metal layer by electroplating.

18. The method of claim 17, wherein the noble metal layer is used as an electrode for electroplating the conductive metal layer to the noble metal layer.

19. The method of claim 12, wherein an additional metal layer is applied to the noble metal layer by electroless plating, and the conductive metal layer is applied to the additional metal layer by electroplating.

20. The method of claim 19, wherein the additional metal layer comprises a member selected from the group consisting of copper, nickel, and cobalt.
